(19) United States
(12) Patent Application Publication
(10) Pub. No.: US 2011/0095280 A1
(43) Pub. Date: Apr. 28, 2011

(54) NOVEL POLYMERS HAVING LOW POLYDISPERSITY

(76) Inventors: Frank Egnon Meyer, Hamshire (GB); Niels Schulte, Kelkheim (DE); Willi Kreuder, Mainz (DE)

(21) Appl. No.: 13/001,221

(22) PCT Filed: Sep. 2, 2009
(86) PCT No.: PCT/EP09/06355

§ 371 Date: Dec. 23, 2010

(30) Foreign Application Priority Data
Sep. 25, 2008 (DE) 10-2008-049-037.7

(51) Int. Cl. H01L 51/30; C08G 79/08; C08L 85/04

(52) U.S. Cl. 257/40; 528/8; 524/610; 525/389; 524/500; 257/E51.027

(57) ABSTRACT

The present invention relates to novel polymers which comprise one or more recurring units selected from spirobifluorene, indenofluorene, phenanthrene, dihydrophenanthrene, dihydropyrene, tetrahydropyrene and dihydrobenzoxepine derivatives and have low polydispersity and a high molecular weight, to a process for the preparation thereof, to blends and formulations comprising these polymers, and to the use of these polymers in electronic devices, in particular in organic light-emitting diodes, so-called OLEDs (OLED=organic light-emitting diode).

The present invention relates to novel polymers which comprise one or more recurring units selected from spirobifluorene, indenofluorene, phenanthrene, dihydrophenanthrene, dihydropyrene, tetrahydropyrene and dihydrobenzoxepine derivatives and have low polydispersity and a high molecular weight, to a process for the preparation thereof, to blends and formulations comprising these polymers, and to the use of these polymers in electronic devices, in particular in organic light-emitting diodes, so-called OLEDs (OLED=organic light-emitting diode). The polymers according to the invention exhibit a relatively long lifetime, in particular on use in OLEDs.

Conjugated polymers have already been investigated intensively for some time as highly promising materials in OLEDs. OLEDs which comprise polymers as organic materials are frequently also known as PLEDs (PLED=polymeric light-emitting diode). Their simple preparation promises inexpensive production of corresponding light-emitting diodes.

Since PLEDs usually only consist of one light-emitting layer, polymers are required which are able to combine as far as possible all functions (charge injection, charge transport, recombination) of an OLED in themselves. In order to meet these requirements, different monomers which take on the corresponding functions are employed during the polymerisation. Thus, it is generally necessary, for the generation of all three emission colours, to copolymerise certain comonomers into the corresponding polymers (cf., for example, WO 00/046321 A1, WO 03/020790 A2 and WO 02/077060 A1). Thus, it is possible, for example starting from a blue-emitting base polymer (“backbone”), to generate the two other primary colours red and green.

Polymers which have already been proposed or developed for full-colour display elements (full-colour displays) are various classes of material, such as, for example, poly-para-phenylenes (PPPs). Thus, for example, polyfluorene derivatives (as disclosed, for example, in EP 0842208, WO 99/54385, WO 00/22027, WO 00/22026 and WO 00/46321), polyspirobifluorene derivatives (as disclosed, for example, in EP 0707020, EP 0894107 and WO 03/020790), polyindenofluorene derivatives, polyphenanthrene derivatives and polydihydrophenanthrene derivatives (as disclosed, for example, in WO 2005/014689) come into consideration. It is also possible to use a combination of two or more of these monomer units, as described, for example, in WO 02/077060.

The most important criteria of an OLED are efficiency, colour and lifetime. Since these properties are crucially determined by the polymer(s) used, improvements in these materials compared with the materials known from the prior art continue to be desired.

Starting from the known prior art, it can be regarded as one of the objects of the present invention to provide novel polymers having improved properties, in particular a longer lifetime.

Surprisingly, it has now been found that polymers which comprise one or more recurring units selected from spirobifluorene, indenofluorene, phenanthrene, dihydrophenanthrene, dihydropyrene, tetrahydropyrene and dihydrobenzoxepine derivatives and have low polydispersity, i.e. a narrow molecular-weight distribution, have a significantly longer lifetime compared with the same materials having a broad molecular-weight distribution.

The present invention thus relates to polymers which comprise at least 1 to 100 mol % of one or more recurring units selected from spirobifluorene, indenofluorene, phenanthrene, dihydrophenanthrene, dihydropyrene, tetrahydropyrene and dihydrobenzoxepine derivatives, which are characterised in that they have a polydispersity D (=M_{w}/Mₙ) of ≦2.0 and a molecular weight M_{w} of ≧100,000 g/mol (determined by GPC against polystyrene standards).

The polydispersity D is taken to mean the quotient of the weight average molecular weight M_{w} and the number average molecular weight Mₙ:D=M_{w}/Mₙ.

Both the weight average molecular weight and the number average molecular weight of the polymers according to the invention are determined by gel permeation chromatography (GPC).

The polymers according to the invention preferably have a polydispersity of ≦1.9 and particularly preferably ≦1.8.

In addition, the polymers according to the invention preferably have a molecular weight M_{w} ≧200,000 g/mol and particularly preferably ≧300,000 g/mol.

Preference is given to spirobifluorene derivatives of the formula (I):

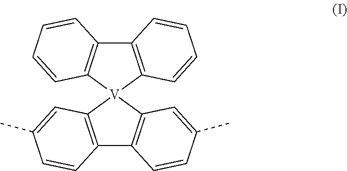

in which V=C, Si or Ge, preferably C.

Particular preference is given to 9,9′-spirobifluorene derivatives of the formula (Ia):

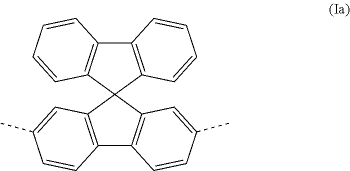

Preferred indenofluorene derivatives are both trans-indenofluorene derivatives of the formula (II) and cis-indenofluorene derivatives of the formula (III):

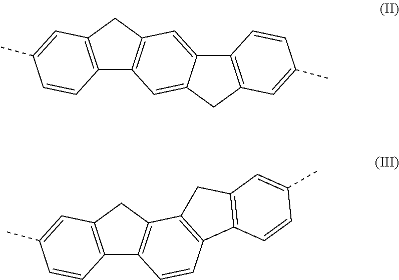

Preference is furthermore given to phenanthrene derivatives of the formula (IV) and 9,10-dihydrophenanthrene derivatives of the formula (V):

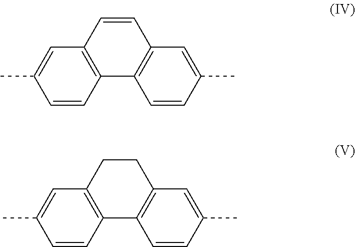

Preference is furthermore given to 4,5-dihydropyrene derivatives of the formula (VI) and 4,5,9,10-tetrahydropyrene derivatives of the formula (VII):

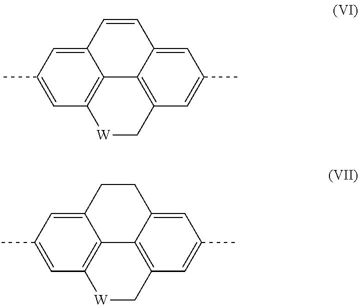

in which W=CR₂, O, S or Se, preferably CR₂.

Particular preference is given here to 4,5-dihydropyrene derivatives of the formula (VIa) and 4,5,9,10-tetrahydropyrene derivatives of the formula (VIIa):

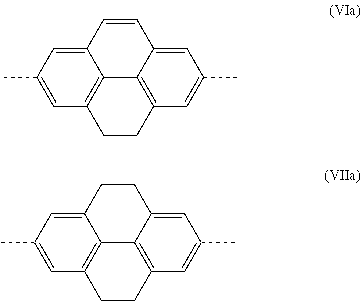

Preference is furthermore given to 5,7-dihydrodibenzoxepine derivatives of the formula (VIII):

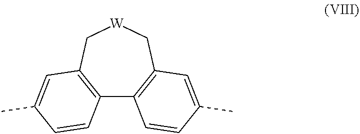

in which W=CR₂, O, S or Se, preferably CR₂.

Particular preference is given to 5,7-dihydrodibenzoxepine derivatives of the formula (VIIIa):

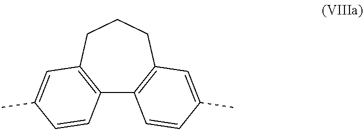

The various formulae (I) to (VIII) and (Ia), (VIa) to (VIIIa) may additionally also be substituted by one or more substituents R¹ in the free positions.

R and R¹ are on each occurrence, identically or differently, H, a straight-chain, branched or cyclic alkyl or alkoxy chain having 1 to 22 C atoms, in which, in addition, one or more non-adjacent C atoms may be replaced by O, S, CR²=CR², C≡C, CO, O—CO, CO—O or O—CO—O and in which one or more H atoms may be replaced by fluorine, an aryl or aryloxy group having 5 to 40 C atoms, in which, in addition, one or more C atoms may be replaced by O, S or N, which may also be substituted by one or more non-aromatic radicals R¹, or F, CN, N(R²)₂ or B(R²)₂; and

R² is on each occurrence, identically or differently, H, a straight-chain, branched or cyclic alkyl chain having 1 to 22 C atoms, in which, in addition, one or more non-adjacent C atoms may be replaced by O, S, CO, O—CO, CO—O or O—CO—O and in which one or more H atoms may be replaced by fluorine, or an optionally substituted aryl group having 5 to 40 C atoms, in which, in addition, one or more C atoms may be replaced by O, S or N.

Preferred alkyl groups are methyl, ethyl, n-propyl, isopropyl, n-butyl, isobutyl, s-butyl, t-butyl, 2-methylbutyl, n-pentyl, s-pentyl, cyclopentyl, n-hexyl, cyclohexyl, 2-ethylhexyl, n-heptyl, cycloheptyl, n-octyl, cyclooctyl, dodecanyl, trifluoromethyl, perfluoro-n-butyl, 2,2,2-trifluoroethyl, perfluorooctyl and perfluorohexyl.

Preferred alkenyl groups are ethenyl, propenyl, butenyl, pentenyl, cyclopentenyl, hexenyl, cyclohexenyl, heptenyl, cycloheptenyl, octenyl and cyclooctenyl.

Preferred alkynyl groups are ethynyl, propynyl, butynyl, pentynyl, hexynyl and octynyl.

Preferred alkoxy groups are methoxy, ethoxy, 2-methoxyethoxy, n-propoxy, i-propoxy, n-butoxy, i-butoxy, s-butoxy, t-butoxy, 2-methylbutoxy, n-pentoxy, n-hexoxy, n-heptoxy and n-octoxy.

Preferred aryl groups are phenyl, biphenyl, triphenyl, [1,1′:3′,1″]terphenyl-2′-yl, naphthyl, anthracene, binaphthyl, phenanthrene, dihydrophenanthrene, pyrene, dihydropyrene, chrysene, perylene, tetracene, pentacene, benzopyrene, fluorene, indene, indenofluorene and spirobifluorene.

Preferred heteroaryl groups are 5-membered rings, such as, for example, pyrrole, pyrazole, imidazole, 1,2,3-triazole, 1,2,4-triazole, tetrazole, furan, thiophene, selenophene, oxazole, isoxazole, 1,2-thiazole, 1,3-thiazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 6-membered rings, such as, for example, pyridine, pyridazine, pyrimidine, pyrazine, 1,3,5-triazine, 1,2,4-triazine, 1,2,3-triazine, 1,2,4,5-tetrazine, 1,2,3,4-tetrazine, 1,2,3,5-tetrazine, or condensed groups, such as, for example, indole, isoindole, indolizine, indazole, benzimidazole, benzotriazole, purine, naphthimidazole, phenanthrimidazole, pyridimidazole, pyrazinimidazole, quinoxalinimidazole, benzoxazole, naphthoxazole, anthroxazole, phenanthroxazole, isoxazole, benzothiazole, benzofuran, isobenzofuran, dibenzofuran, quinoline, isoquinoline, pteridine, benzo-5,6-quinoline, benzo-6,7-quinoline, benzo-7,8-quinoline, benzisoquinoline, acridine, phenothiazine, phenoxazine, benzopyridazine, benzopyrimidine, quinoxaline, phenazine, naphthyridine, azacarbazole, benzocarboline, phenanthridine, phenanthroline, thieno[2,3b]thiophene, thieno[3,2b]thiophene, dithienothiophene, isobenzothiophene, dibenzothiophene, benzothiadiazothiophene, or combinations of these groups.

The aryl and heteroaryl groups may also be substituted by alkyl, alkoxy, thioalkyl, fluorine, fluoroalkyl or further aryl or heteroaryl groups.

In a preferred embodiment, the polymer according to the invention comprises 10 to 99 mol % and particularly preferably 30 to 98 mol % of one or more structural units selected from the formulae (I) to (VIII).

The polymers according to the invention are conjugated, partially conjugated or non-conjugated polymers. However, preference is given to conjugated and partially conjugated polymers, particularly preferably conjugated polymers.

Conjugated polymers in the sense of the present application are polymers which contain principally sp²-hybridised carbon atoms, which may also be replaced by corresponding heteroatoms, in the main chain. In the simplest case, this means the alternating presence of double and single bonds in the main chain. Principally means that naturally occurring defects which result in conjugation interruptions do not devalue the term “conjugated polymer”. Furthermore, the term conjugated is likewise used in this application text if, for example, arylamine units and/or certain heterocycles (i.e. conjugation via N, O, or S atoms) and/or organometallic complexes (i.e. conjugation via the metal atom) are located in the main chain. By contrast, units such as, for example, simple alkyl bridges, (thio)ether, ester, amide or imide links are clearly defined as non-conjugated segments. A partially conjugated polymer is intended to be taken to mean a polymer in which relatively long conjugated segments in the main chain are interrupted by non-conjugated segments, or which contains relatively long conjugated segments in the side chains of a polymer which is non-conjugated in the main chain.

The polymers according to the invention are either homopolymers selected from structural units of the formulae (I) to (VIII) or copolymers. The polymers according to the invention may be linear, branched or crosslinked.

The copolymers according to the invention can have random, alternating or block-like structures or also have a plurality of these structures in an alternating arrangement. The way in which copolymers having block-like structures can be obtained and the further structural elements that are particularly preferred for this purpose are described in detail, for example, in WO 2005/014688 A2. It should likewise be emphasised at this point that the polymer may also have dendritic structures besides linear structures.

Besides one or more structural units of the formulae (I) to (VIII), the polymers according to the invention may also contain further structural elements. These are, inter alia, those as are disclosed and listed extensively in WO 02/077060 A1 and in DE 10337346 A1. The further structural units may originate, for example, from the following classes:
Group 1: Units which influence the hole-injection and/or -transport properties of the polymers;
Group 2: Units which influence the electron-injection and/or -transport properties of the polymers;
Group 3: Units which have combinations of individual units from group 1 and group 2;
Group 4: Units which modify the emission characteristics to such an extent that electrophosphorescence can be obtained instead of electrofluorescence;
Group 5: Units which improve the transfer from the so-called singlet state to the triplet state;
Group 6: Units which influence the morphology and/or the emission colour of the resultant polymers;
Group 7: Units which emit light.

Preferred polymers according to the invention are those in which at least one structural element has charge-transport properties, i.e. which comprise units from groups 1 and/or 2.

Structural elements from group 1 which have hole-transport properties are, for example, triarylamine, benzidine, tetraaryl-para-phenylenediamine, triarylphosphine, phenothiazine, phenoxazine, dihydrophenazine, thianthrene, dibenzo-para-dioxin, phenoxathiyne, carbazole, azulene, thiophene, pyrrole and furan derivatives and further O- , S- or N-containing heterocycles having a high HOMO (HOMO=highest occupied molecular orbital). These arylamines and heterocycles preferably result in an HOMO in the polymer of greater than −5.8 eV (against vacuum level), particularly preferably greater than −5.5 eV.

Structural elements from group 2 which have electron-transport properties are, for example, pyridine, pyrimidine, pyridazine, pyrazine, oxadiazole, quinoline, quinoxaline and phenazine derivatives, but also triarylboranes and further O-, S- or N-containing heterocycles having a low LUMO (LUMO=lowest unoccupied molecular orbital). These units in the polymer preferably result in an LUMO of less than −1.5 eV (against vacuum level), particularly preferably less than −2.0 eV.

It may be preferred for the polymers according to the invention to comprise units from group 3 in which structures which increase the hole mobility and structures which increase the electron mobility (i.e. units from groups 1 and 2) are bonded directly to one another. Some of these units can serve as emitters and shift the emission colour into the green, yellow or red. Their use is thus suitable, for example, for the generation of other emission colours from originally blue emitting polymers.

Structural units from group 4 are those which are able to emit light from the triplet state with high efficiency, even at room temperature, i.e. exhibit electrophosphorescence instead of electrofluorescence, which frequently causes an increase in the energy efficiency. Suitable for this purpose are firstly compounds which contain heavy atoms having an atomic number of greater than 36. Preference is given to compounds which contain d or f transition metals which meet the above-mentioned condition. Particular preference is given here to corresponding structural units which contain elements from groups 8 to 10 (Ru, Os, Rh, Ir, Pd, Pt). Suitable structural units for the polymers according to the invention here are, for example, various complexes, as described, for example, in WO 02/068435 A1, DE 10116962 A1, EP 1239526 A2 and DE 10238903 A1 . Corresponding monomers are described in WO 02/068435 A1 and in DE 10350606 A1.

Structural elements from group 5 are those which improve the transfer from the singlet state to the triplet state and which, employed in support of the structural elements from group 4, improve the phosphorescence properties of these structural elements. Suitable for this purpose are, in particular, carbazole and bridged carbazole dimer units, as described in DE 10304819 A1and DE 10328627 A1. Also suitable for this purpose are ketones, phosphine oxides, sulfoxides and similar compounds, as described in DE 10349033 A1.

Structural elements from group 6 which influence the morphology and/or the emission colour of the polymers, besides those mentioned above, are those which have at least one further aromatic or other conjugated structure which does not fall under the above-mentioned groups, i.e. which have only little influence on the charge-carrier mobilities, are not organometallic complexes or do not influence the singlet-triplet transfer. Structural elements of this type can influence the morphology and/or the emission colour of the resultant polymers. Depending on the unit, they can therefore also be employed as emitters. Preference is given here to aromatic structures having 6 to 40 C atoms and also tolan, stilbene or bisstyrylarylene derivatives, each of which may be substituted by one or more radicals R¹. Particular preference is given here to the incorporation of 1,4-phenylene, 1,4-naphthylene, 1,4- or 9,10-anthrylene, 1,6-, 2,7- or 4,9-pyrenylene, 3,9- or 3,10-perylenylene, 4,4′-biphenylylene, 4,4″-terphenylylene, 4,4′-bi-1,1′-naphthylylene, 4,4′-tolanylene, 4,4′-stilbenylene or 4,4″-bisstyrylarylene derivatives.

Structural elements from group 7 which emit light are preferably units which emit blue, green or red.

Suitable blue-emitting units are typically units which are generally used as polymer backbone. These are generally those which have at least one aromatic or other conjugated structure, but do not shift the emission colour into the green or into the red.

Preference is given to aromatic structures having 4 to 40 C atoms, but also stilbene and tolan derivatives and bis(styryl)arylene derivatives. These are, for example, the following structural elements, which may be substituted or unsubstituted: 1,4-phenylene, 1,4-naphthylene, 1,4- or 9,10-anthracenylene, 2,7- or 3,6-phenanthrenylene, 4,4′-biphenylylene, 4,4″-terphenylylene, 4,4′-bi-1,1′-naphthylylene, 4,4′-stilbene derivatives, 9,10-dihydropyrene derivatives, 4,5,9,10-tetrahydropyrene derivatives (for example in accordance with EP-A-699699), fluorene derivatives (for example in accordance with EP-A-0 842 208, WO 99/54385, WO 00/22027, WO 00/22026, WO 00/46321), spirobifluorene derivatives (for example in accordance with EP-A-0 707 020, EP-A-0 894 107, WO 03/020790, WO 02/077060), 5,7dihydrodibenzoxepine derivatives, cis- and trans-indenofluorene derivatives (for example in accordance with GB 0226010 and EP 03014042) and 9,10-dihydrophenanthrene derivatives (for example in accordance with DE 10337346). Besides these classes, the so-called ladder PPPs (LPPPs) (for example in accordance with WO 92/18552), but also PPPs containing ansa structures (for example in accordance with EP-A-690086), for example, are also suitable here. Bis(styryl)arylene derivatives, which are not electron-rich, can also be used for this purpose.

It may also be preferred for more than one such blue-emitting structural unit to be used in the polymer according to the invention.

If the polymer according to the invention comprises green-emitting structural units, suitable structural units for this purpose are preferably those which have at least one aromatic or other conjugated structure and shift the emission colour into the green. Preferred structures for green emitting units are selected from the groups of the electron-rich bisstyrylarylenes and derivatives of these structures.

Further preferred green-emitting structural units are selected from the groups of the benzothiadiazoles and corresponding oxygen derivatives, the quinoxalines, the phenothiazines, the phenoxazines, the dihydrophenazines, the bis(thiophenyl)arylenes, the oligo(thiophenylenes) and the phenazines. It is also permissible here to use a plurality of different green-emitting structural units instead of one, in which case the total proportion of the green-emitting units is a maximum of 20 mol %, preferably a maximum of 10 mol % and particularly preferably a maximum of 3 mol %.

Suitable red-emitting structural units are preferably units which have at least one aromatic or other conjugated structure and shift the emission colour into the red. Preferred structures for red-emitting units are those in which electron-rich units, such as, for example, thiophene, are combined with green-emitting electron-deficient units, such as, for example, quinoxaline or benzothiadiazole. Further preferred red-emitting units are systems comprising at least four condensed aromatic units, such as, for example, rubrenes, pentacenes or perylenes, which are preferably substituted, or preferably conjugated push-pull systems (systems which are substituted by donor and acceptor substituents) or systems such as squarines or quinacridones, which are preferably substituted. It is also permissible here to use a plurality of red-emitting units instead of one, in which case the total proportion of the red-emitting units is a maximum of 10 mol %, preferably a maximum of 5 mol % and particularly preferably a maximum of 1 mol %.

Suitable blue-, green- and red-emitting structural units are in principle also units which emit light from the triplet state, i.e. exhibit electrophosphorescence instead of electrofluorescence, which frequently causes an increase in the energy efficiency. These units are referred to as triplet emitters below. The use of metal complexes of this type in low-molecular-weight OLEDs is described, for example, in M. A. Baldo et al. (Appl. Phys. Lett. 1999, 75, 4-6).
Suitable for this purpose are firstly compounds which contain heavy atoms, i.e. atoms from the Periodic Table of the Elements having an atomic number of greater than 36.
Particularly suitable for this purpose are compounds which contain d and f transition metals which meet the above-mentioned condition. Very particular preference is given here to corresponding structural units which contain elements from groups 8 to 10 (i.e. Ru, Os, Rh, Ir, Pd, Pt).
Suitable structural units for the polymers according to the invention are, for example, various complexes, which are described, for example, in WO 02/068435, DE 10116962 A1, EP 1239526 and DE 10238903 A1.

Corresponding compounds are described in WO 02/068435.

The colours of the complexes here are determined primarily by the metal used, by the precise ligand structure and by the substituents on the ligand. Both green- and red-emitting complexes are known. Thus, for example, an unsubstituted tris(phenylpyridyl)iridium(III) emits green light, while electrondonating substituents in the para-position to the coordinating carbon atom (for example diarylamino substituents) shift the emission into the orange-red. Also known are derivatives of this complex with a varied ligand structure which result directly (without further substitutions) in orange or deep-red emission. Examples of such ligands are 2-phenylisoquinoline, 2-benzothiophenylpyridine and 2-naphthylpyridine.

Blue-emitting complexes are obtained, for example, by substituting the tris(phenylpyridyl)iridium(III) skeleton by electron-withdrawing substituents, such as, for example, a plurality of fluorine and/or cyano groups.

Preferred fluorescent emitters of the present invention are selected from the class of the monostyrylamines, the distyrylamines, the tristyrylamines, the tetrastyrylamines and the arylamines, each of which are substituted by a fluorine radical. A monostyrylamine is taken to mean a compound which contains one styryl group and at least one amine, which is preferably aromatic. A distyrylamine is taken to mean a compound which contains two styryl groups and at least one amine, which is preferably aromatic. A tristyrylamine is taken to mean a compound which contains three styryl groups and at least one amine, which is preferably aromatic. A tetrastyrylamine is taken to mean a compound which contains four styryl groups and at least one amine, which is preferably aromatic. An arylamine or an aromatic amine in the sense of the present invention is taken to mean a compound which contains three aromatic or heteroaromatic ring systems bonded directly to the nitrogen, at least one of which is preferably a condensed ring system having at least 14 aromatic ring atoms. The styryl groups are particularly preferably stilbenes, which may also be further substituted on the double bond or on the aromatic rings. Examples of compounds of this type are substituted or unsubstituted tristilbenamines or further compounds which are described, for example, in WO 06/000388, WO 06/058737, WO 06/000389, DE 102005058543 A1 and DE 102006015183 A1. Preference is furthermore given to compounds in accordance with WO 06/122630 and in accordance with DE 102006025846 A1 as emitters.

A phosphorescent emitter compound is preferably selected from the class of the metal complexes containing at least one element having an atomic number of greater than 20, preferably greater than 38 and less than 84, particularly preferably greater than 56 and less than 80. Preference is given to the use of metal complexes which contain copper, molybdenum, tungsten, rhenium, ruthenium, osmium, rhodium, iridium, palladium, platinum, silver, gold or europium, in particular iridium. In general, phosphorescent materials, as are used in accordance with the prior art, are suitable for this purpose.

The use of a plurality of different structural elements enables adjustment of properties such as solubility, solid-phase morphology, colour, charge-injection and -transport properties, temperature stability, electro-optical characteristics, etc.

The requisite solubility of the polymers is ensured, in particular, by the substituents on the various recurring units.

The polymers according to the invention are generally prepared by polycondensation of one or more types of monomer, at least one of which results in structural units selected from the formulae (I) to (VIII) in the polymer. Suitable polycondensation reactions are known to the person skilled in the art and are described in the literature. Particularly suitable and preferred polycondensation reactions which result in C—C or C—N links are:
(A) SUZUKI polycondensation;
(B) YAMAMOTO polycondensation;
(C) STILLEpolycondensation;
(D) HECK polycondensation;
(E) NEGISHI polycondensation;
(F) SONOGASHIRA polycondensation;
(G) HIYAMA polycondensation; and
(H) HARTWIG-BUCHWALD polycondensation.

The way in which the polycondensation can be carried out by these processes and the way in which the polymers can then be separated off from the reaction medium and purified are known to the person skilled in the art and is described in detail in the literature, for example in WO 03/048225 A2, WO 2004/037887 A2 and WO 2004/037887 A2.

The C—C linking reactions are preferably selected from the groups of the SUZUKI coupling, the YAMAMOTO coupling and the STILLE coupling; the C—N linking reaction is preferably a HARTWIG-BUCHWALD coupling.

In order to obtain the desired polydispersities, it is generally necessary to subject the polymers prepared by the processes described above to a separation process. All separation processes known to the person skilled in the art can be used for this purpose.

However, preference is given to fractionation of the resultant polymers by a process as is disclosed, for example, in DE 102 02 591 A1. This application discloses a process for the fractionation of polymers, which is characterised in that a polymer solution (donor phase) is forced through a spinneret or through a plurality of spinnerets into a mixing zone which contains a vigorously agitated precipitation bath (receiver phase), with a two-phase mixture comprising a sol phase and a gel phase forming, and the sol phase and the gel phase are separated from one another. The corresponding device for carrying out this process is likewise disclosed in DE 102 02 591 A1.

Preferred embodiments of this process are characterised in that:
the sol phase and gel phase are separated in a rest zone following the mixing zone,
the sol phase and gel phase are removed continuously from the rest zone;
different temperatures are set within the rest zone in the region of the sol removal and the gel removal;
the precipitation bath is a solvent or solvent mixture which preferably takes up the more readily soluble constituents of the polymer to be fractionated;
the donor phase is a concentrated, homogeneous solution of the polymer to be fractionated;
the polymer solution is forced through the spinneret(s) with the aid of a pump;
the receiver phase comprises a homopolymer as auxiliary polymer;
and/or the fractionation takes place in accordance with the molecular weight.

The present invention thus also relates to a process for the preparation of the polymers according to the invention, which is characterised in that they are prepared by SUZUKI polycondensation, YAMAMOTO polycondensation, STILLE polycondensation or HARTWIG-BUCHWALD polycondensation and are subsequently fractionated.

For the synthesis of the polymers according to the invention, the corresponding monomers are required. The synthesis of the monomers which result in units of the formulae (I) to (VIII) and in the units described in groups 1 to 7 in the polymers according to the invention is known to the person skilled in the art and is described in the literature, for example in WO 2005/014689 A2, WO 2005/030827 A1 and WO 2005/030828 A1.

It may additionally be preferred to use the polymers according to the invention not as the pure substance, but instead as a blend (mixture) together with further polymeric, oligomeric, dendritic or low-molecular-weight substances of any desired type. These may, for example, improve the electronic properties, influence the transfer from the singlet state to the triplet state or themselves emit light from the singlet state or from the triplet state. However, electronically inert substances may also be appropriate in order, for example, to influence the morphology of the polymer film formed or the viscosity of polymer solutions. Above and below, a blend denotes a mixture comprising at least one polymeric component.

The present invention thus furthermore relates to a polymer blend comprising one or more polymers according to the invention and one or more further polymeric, oligomeric, dendritic or low-molecular-weight substances.

The present invention furthermore relates to solutions and formulations comprising one or more polymers or blends according to the invention in one or more solvents. The way in which solutions of this type can be prepared is known to the person skilled in the art and is described, for example, in WO 02/072714 A1, in WO 03/019694 A2 and in the literature cited therein. These solutions can be used to produce thin polymer layers, for example by area-coating processes (for example spin coating) or printing processes (for example ink-jet printing).

Polymers comprising structural units selected from the formulae (I) to (VIII) which contain one or more polymerisable and thus crosslinkable groups are particularly suitable for the production of films or coatings, in particular for the production of structured coatings, for example by thermal or light-induced in-situ polymerisation and in-situ crosslinking, such as, for example, in-situ UV photopolymerisation or photopatterning. For applications of this type, particular preference is given to polymers according to the invention containing one or more polymerisable groups, for example selected from acrylate, methacrylate, vinyl, epoxide and oxetane. It is possible here not only to use corresponding polymers as the pure substance, but also to use formulations or blends of these polymers as described above. These can be used with or without addition of solvents and/or binders. Suitable materials, processes and devices for the methods described above are described, for example, in WO 2005/083812 A2. Possible binders are, for example, polystyrene, polycarbonate, polyacrylates, polyvinylbutyral and similar, opto-electronically neutral polymers.

Suitable and preferred solvents are, for example, toluene, anisole, xylene, methyl benzoate, dimethylanisole, mesitylene, tetralin, veratrol and tetrahydrofuran.

The polymers, blends and formulations according to the invention can be used in electronic or opto-electronic devices or for the production thereof.

The present invention thus furthermore relates to the use of the polymers, blends and formulations according to the invention in electronic or opto-electronic devices, preferably in organic or polymeric organic light-emitting diodes (OLEDs, PLEDs), organic field-effect transistors (O-FETs), organic integrated circuits (O-ICs), organic thin-film transistors (O-TFTs), organic solar cells (O-SCs), organic laser diodes (O-lasers), organic photovoltaic (OPV) elements or devices or organic photoreceptors (OPCs), particularly preferably in organic or polymeric organic light-emitting diodes (OLEDs, PLEDs), in particular in polymeric organic light-emitting diodes (PLEDs).

Polymeric organic light-emitting diodes comprise a cathode, an anode, an emission layer and optionally further layers, such as, for example, preferably a hole-injection layer, and optionally an interlayer between the hole-injection layer and the emission layer.

The way in which OLEDs or PLEDs can be produced is known to the person skilled in the art and is described in detail, for example, as a general process in WO 2004/070772 A2, which should be adapted correspondingly for the individual case.

As described above, the polymers according to the invention are very particularly suitable as electroluminescent materials in PLEDs or displays produced in this way.

For the purposes of the present invention, electroluminescent materials are taken to mean materials which can be used as active layer. Active layer means that the layer is capable of emitting light on application of an electric field (light-emitting layer) and/or that it improves the injection and/or transport of positive and/or negative charges (charge-injection or charge-transport layer). It may also be an interlayer between a hole-injection layer and an emission layer.

The present invention therefore also preferably relates to the use of the polymers or blends according to the invention in a PLED, in particular as electroluminescent material.

The present invention furthermore relates to electronic or opto-electronic components, preferably organic or polymeric organic light-emitting diodes (OLEDs, PLEDs), organic field-effect transistors (O-FETs), organic integrated circuits (O-ICs), organic thin-film transistors (O-TFTs), organic solar cells (O-SCs), organic laser diodes (O-lasers), organic photovoltaic (OPV) elements or devices or organic photoreceptors (OPCs), particularly preferably organic or polymeric organic light-emitting diodes, in particular polymeric organic light-emitting diodes, having one or more active layers, where at least one of these active layers comprises one or more polymers according to the invention. The active layer can be, for example, a light-emitting layer, a charge-transport layer, a charge-injection layer and/or an interlayer.

The present application text and also the examples below are principally directed to the use of the polymers according to the invention in relation to PLEDs and corresponding displays. In spite of this restriction of the description, it is possible for the person skilled in the art, without further inventive step, also to use the polymers according to the invention as semiconductors for the further uses described above in other electronic devices.

The invention is described in greater detail below with reference to working examples, but without being restricted thereby. In particular, the features, properties and advantages described therein of the defined compounds on which the relevant example is based can also be applied to other compounds which are not described in detail, but fall within the scope of protection of the claims, unless stated otherwise elsewhere.

### EXAMPLES

A) Preparation of the polymers

### Examples 1 to 3

Firstly, three polymers 1 to 3 are prepared using the following monomers (per cent data=mol %) by SUZUKI coupling in accordance with WO 03/048225 A2.

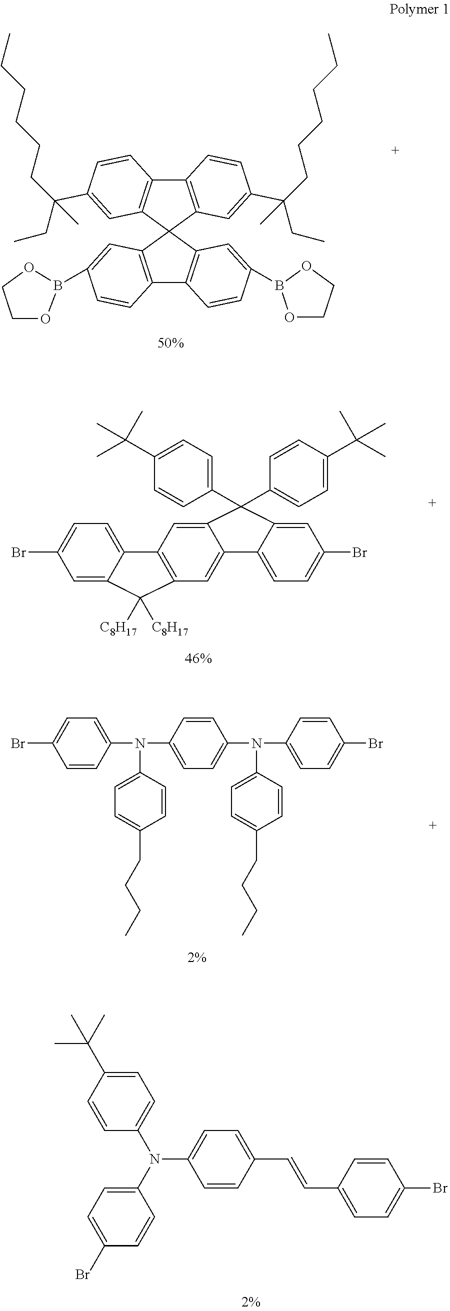

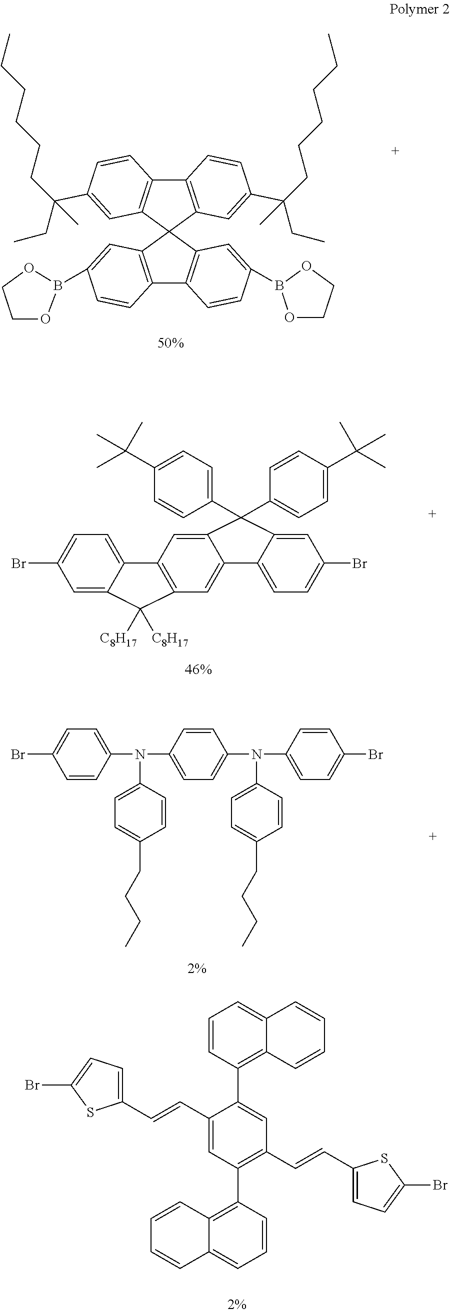

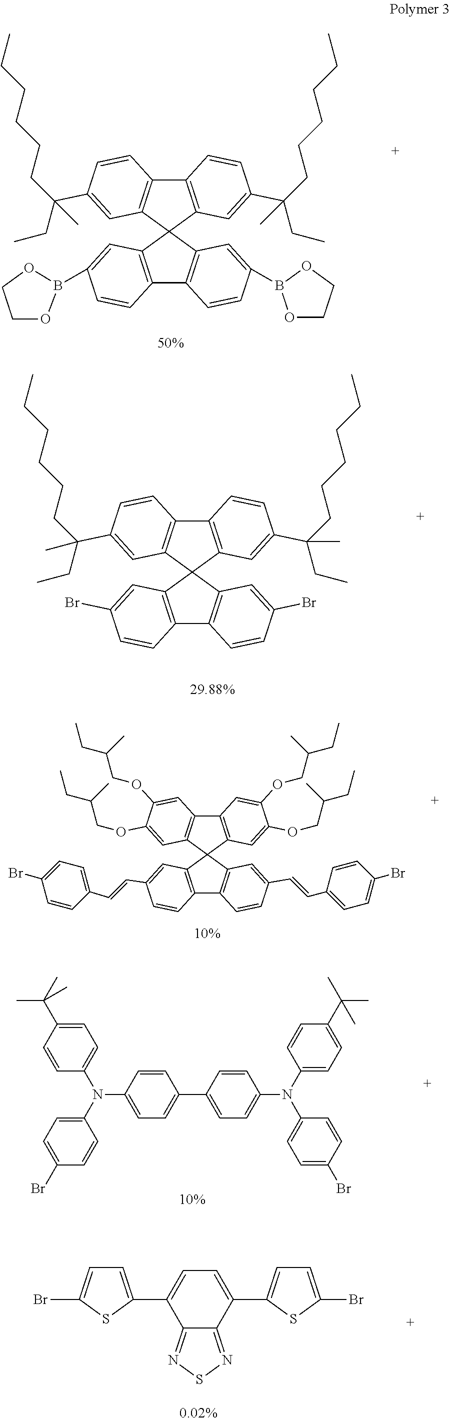

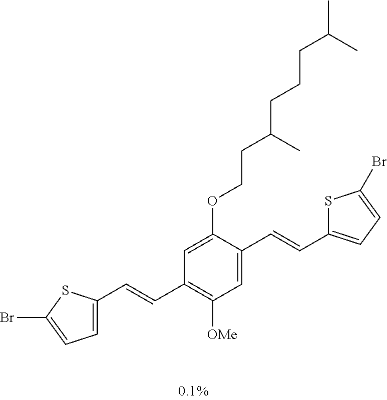

B) Fractionation of the resultant polymers

### Examples 4 to 6

Polymers 1 to 3 are fractionated by the process described in WO 03/062282 A1. In all experiments, a 1% solution of the polymer in toluene as “donor phase” is employed. Ethanol serves as “receiver phase” in all examples. The results of the fractionation of polymers 1 to 3 are shown in Table 1 below. Fractions 1.1 and 1.2 are obtained from polymer 1, fraction 2.1 is obtained from polymer 2, and fractions 3.1 and 3.2 are obtained correspondingly from polymer 3.

TABLE 1

| Example | Polymer | M_{w} [g/mol] | Mₙ [g/mol] | M_{w}/Mₙ |
|---|---|---|---|---|
| Example 4 | Polymer 1 | 385000 | 118000 | 3.26 |
| | Polymer 1.1 | 376000 | 219000 | 1.71 |
| | Polymer 1.2 | 286000 | 181000 | 1.58 |
| Example 5 | Polymer 2 | 564000 | 161000 | 3.50 |
| | Polymer 2.1 | 466000 | 260000 | 1.79 |
| Example 6 | Polymer 3 | 656000 | 133000 | 4.93 |
| | Polymer 3.1 | 511000 | 271000 | 1.88 |
| | Polymer 3.2 | 235000 | 150000 | 1.57 |

Description of the measurement method(s):

The molecular weights M_{w} and Mₙ were determined by GPC (model: Agilent HPLC system series 1100) (column: PL-RapidH from Polymer Laboratories; solvent: THF comprising 0.12% by vol. of o-dichlorobenzene; detection: UV and refractive index; temperature: 40° C.). The calibration was carried out using polystyrene standards.

C) OLED devices comprising the fractionated polymers

### Examples 7 to 14

### Production of a PLED

The production of a polymeric organic light-emitting diode has already been described a number of times in the literature (for example in WO 2004/037887 A2). In order to explain the present invention by way of example, PLEDs comprising fractionated polymers 1.1 and 1.2, 2.1 and 3.1 and 3.2 are produced by spin coating onto ITO substrates coated in advance with PEDOT and a hole-injecting interlayer (PEDOT is a polythiophene derivative (Baytron P from H. C. Starck, Goslar)). The layer thickness of the polymer layer is about 80 nm. A Ba/AI cathode (metals from Aldrich) is then applied by vapour deposition, and the PLED iss encapsulated and characterised electro-optically.

The results obtained in PLEDs on use of polymers 1, 2 and 3 and fractionated polymers 1.1 and 1.2, 2.1 and 3.1 and 3.2 prepared from these polymers are shown in Table 2 below.

TABLE 2

| | Poly- | Max. eff. | U@100 cd/m² | | Lifetime |
|---|---|---|---|---|---|
| Example | mer | [cd/A] | [V] | CIE [x/y] | [h @ cd/m²] |
| 7 | 1 | 6.60 | 5.16 | 0.15/0.18 | 385@1000 |
| 8 | 1.1 | 6.83 | 4.33 | 0.15/0.18 | 560@1000 |
| 9 | 1.2 | 6.53 | 5.29 | 0.15/0.18 | 423@1000 |
| 10 | 2 | 15.58 | 4.69 | 0.31/0.59 | 400@6000 |
| 11 | 2.1 | 17.70 | 4.95 | 0.30/0.59 | 599@6000 |
| 12 | 3 | 6.78 | 4.10 | 0.39/0.36 | 140@2000 |
| 13 | 3.1 | 6.67 | 4.40 | 0.37/0.37 | 179@2000 |
| 14 | 3.2 | 6.83 | 4.40 | 0.38/0.37 | 163@2000 |

As can be seen from the results, the lifetime of the polymeric, light-emitting materials according to the invention is better than that of the comparative materials. The emission colour and the efficiency are comparable. This shows that the polymeric, light-emitting materials according to the invention are more suitable for use in displays than polymers in accordance with the prior art.

1.-15. (canceled)

16. A polymer which comprise 1 to 100 mol % of one or more recurring units selected from spirobifluorene, indenofluorene, phenanthrene, dihydrophenanthrene, dihydropyrene, tetrahydropyrene and dihydrobenzoxepine derivatives, wherein the polymer has a polydispersity D (=M_{w}/Mₙ)of ≦2.0 and a molecular weight M_{w} of ≧100,000 g/mol.

17. The polymer according to claim 16, wherein the recurring units are selected from spirobifluorene derivatives of the formula (I): 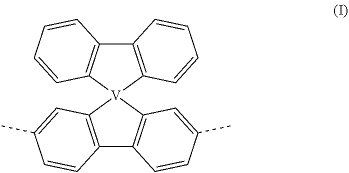
in which V=C, Si or Ge;
trans-indenofluorene derivatives of the formula (II) and cis-indenofluorene derivatives of the formula (III): 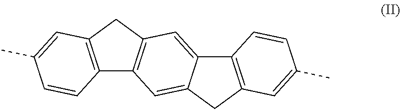 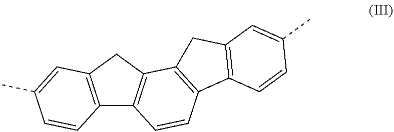
phenanthrene derivatives of the formula (IV) and 9,10-dihydrophenanthrene derivatives of the formula (V): 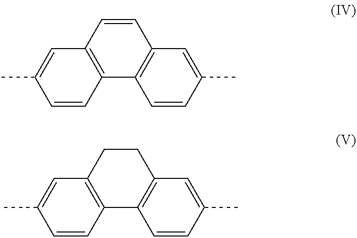
4,5-dihydropyrene derivatives of the formula (VI) and 4,5,9,10-tetrahydropyrene derivatives of the formula (VII): 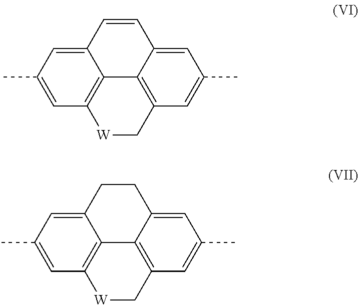
in which W=CR₂, O, S or Se, and
5,7-dihydrodibenzoxepine derivatives of the formula (VIII): 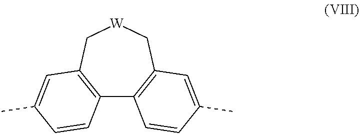
in which W =CR₂, O, S or Se,
wherein
R is on each occurrence, identically or differently, H, a straight-chain, branched or cyclic alkyl or alkoxy chain having 1 to 22 C atoms, in which, in addition, one or more non-adjacent C atoms is optionally replaced by O, S, CR²=CR², C≡C, CO, O—CO, CO—O or O—CO—O and in which one or more H atoms is optionally replaced by fluorine, an aryl or aryloxy group having 5 to 40 C atoms, in which, in addition, one or more C atoms is optionally replaced by O, S or N, which optionally is substituted by one or more non-aromatic radicals R, or F, CN, N(R²)₂ or B(R²)₂; and
R² is on each occurrence, identically or differently, H, a straight-chain, branched or cyclic alkyl chain having 1 to 22 C atoms, in which, in addition, one or more non-adjacent C atoms is optionally replaced by O, S, CO, O—CO, CO—O or O—CO—O and in which one or more H atoms is optionally replaced by fluorine, or an optionally substituted aryl group having 5 to 40 C atoms, in which, in addition, one or more C atoms is optionally replaced by O, S or N.

18. The polymer according to claim 16, wherein the polymer is conjugated or partially conjugated.

19. The polymer according to claim 17, wherein, besides one or more structural units of the formulae (I) to (VIII), further comprise structural elements which enhance the hole-injection and/or -transport properties of the polymers.

20. The polymer according to claim 17, wherein, besides one or more structural units of the formulae (I) to (VIII), further comprise structural elements which enhance the electron-injection and/or -transport properties of the polymers.

21. The polymer according to claim 17, wherein, besides one or more structural units of the formulae (I) to (VIII), further comprise structural elements which modify the emission characteristics to such an extent that electrophosphorescence can be obtained instead of electrofluorescence.

22. The polymer according to claim 17, wherein, besides one or more structural units of the formulae (I) to (VIII), further comprise structural elements which improve the transfer from the so-called singlet state to the triplet state.

23. The polymer according to claim 17, wherein, besides one or more structural units of the formulae (I) to (VIII), further comprise structural elements which influence the morphology and/or the emission colour of the resultant polymers.

24. The polymer according to claim 17, wherein, besides one or more structural units of the formulae (I) to (VIII), further comprise structural elements which emit light.

25. A process for the preparation of the polymer according to claim 16, wherein the polymer is prepared by SUZUKI polycondensation, YAMAMOTO polycondensation, STILLE polycondensation or HARTWIG-BUCHWALD polycondensation and is subsequently fractionated.

26. A polymer blend comprising one or more polymers according to claim 16 and one or more further polymeric, oligomeric, dendritic or low-molecular-weight substances.

27. A solution and formulation comprising one or more polymers according claim 16 in one or more solvents.

28. A solution or formulation comprising one or more blend according to claim 26 in one or more solvents.

29. An electronic or opto-electronic device which comprises the polymer according to claim 16.

30. An electronic or opto-electronic device which comprises the blend according to claim 26.

31. An electronic or opto-electronic device which comprises the formulation according to claim 27.

32. An electronic or opto-electronic components having one or more active layers, where at least one of these active layers comprises one or more polymers according to claim 16.

33. The electronic or opto-electronic component according to claim 32, wherein the component is an organic or polymeric an organic light-emitting diode (OLED, PLED), an organic field-effect transistor (O-FET), an organic integrated circuit (O-IC), an organic thin-film transistor (O-TFT), an organic solar cell (O-SC), an organic laser diode (O-laser), an organic photovoltaic (OPV) element or device or an organic photoreceptor (OPC).
